(19) United States
(12) Patent Application Publication
(10) Pub. No.: US 2024/0363805 A1
(43) Pub. Date: Oct. 31, 2024

(54) SEMICONDUCTOR STRUCTURE AND MANUFACTURING METHOD THEREFOR

(71) Applicant: ENKRIS SEMICONDUCTOR, INC., Suzhou (CN)

(72) Inventor: Kai CHENG, Suzhou (CN)

(73) Assignee: ENKRIS SEMICONDUCTOR, INC., Suzhou (CN)

(21) Appl. No.: 18/485,547

(22) Filed: Oct. 12, 2023

(30) Foreign Application Priority Data
Apr. 27, 2023 (CN) 202310469344.6

(51) Int. Cl. H01L 33/32; H01L 33/00; H01L 33/12

(52) U.S. Cl. CPC H01L 33/32; H01L 33/007; H01L 33/12

(57) ABSTRACT

Disclosed are a semiconductor structure and a manufacturing method therefor. The semiconductor structure includes a first substrate; a mask layer, located on the first substrate; where the mask layer is provided with a window exposing the first substrate, the window includes an open end, and an area of an orthographic projection of the open end on a plane where the first substrate is located is less than an area of an orthographic projection of the window on the plane where the first substrate is located. When a first epitaxial layer is epitaxially grown on the second substrate, a dislocation of the first epitaxial layer terminates at the sidewall, the dislocation may not continue to extend along with a growth of the first epitaxial layer, so that a dislocation density of the semiconductor structure may be reduced, and device characteristic may be improved.

### CROSS-REFERENCE TO RELATED APPLICATIONS

The disclosure claims priority to Chinese Patent Application CN202310469344.6, filed on Apr. 27, 2023, the entire contents of which are incorporated herein by reference.

### TECHNICAL FIELD

The present disclosure relates to the field of semiconductor technologies, and in particular, to a semiconductor structure and a manufacturing method therefor.

### BACKGROUND

With development of science and technology, an III-V compound semiconductor, represented by gallium nitride (GaN), gallium arsenide (GaAs) and indium phosphide (InP), gradually becomes a current research hotspot, and is suitable for production of high-speed, high-frequency, high-power and light-emitting electronic devices. Therefore, the III-V compound semiconductor has a wide application prospect.

There are still many problems to be solved in epitaxial growth of III-V compound on a substrate, such as lattice mismatch between materials, a polarity effect/non-polarity effect, large difference in thermal expansion coefficients and the like, which may easily cause a dislocation of heteroepitaxy. The dislocation is mainly a line dislocation in a crystal orientation. And when a film layer of the III-V compound semiconductor reaches a critical value, cracking is likely to occur, resulting in degradation and effect loss of device performance.

### SUMMARY

In view of this, embodiments of the present disclosure provide a semiconductor structure and a manufacturing method therefor.

According to an aspect of the present disclosure, a semiconductor structure is provided by an embodiment of the present disclosure, including: a first substrate; a mask layer, located on the first substrate, where the mask layer is provided with a window exposing the first substrate, the window includes an open end, and an area of an orthographic projection of the open end on a plane where the first substrate is located is less than an area of an orthographic projection of the window on the plane where the first substrate is located; and a second substrate and a first epitaxial layer, where the second substrate and the first epitaxial layer are located in the window, and the first epitaxial layer is located on a side, away from the first substrate, of the second substrate.

In an embodiment, the window further includes a bottom end located on a surface of the first substrate, and the orthographic projection of the open end on the plane where the first substrate is located is at least partially staggered from the bottom end.

In an embodiment, the window is an oblique columnar window.

In an embodiment, the window further includes a bottom end located on a surface of the first substrate, and an orthographic projection of the open end on the plane where the first substrate is located within an orthographic projection of the bottom end on the plane where the first substrate is located.

In an embodiment, a cross-sectional area of the window gradually decreases in a direction from the bottom end to the open end.

In an embodiment, a material of the second substrate is any one of monocrystalline silicon, monocrystalline germanium, monocrystalline silicon germanium, and monocrystalline silicon carbide.

In an embodiment, a crystal plane, close to the first epitaxial layer, of the second substrate is any one of a (111) crystal plane, a (110) crystal plane and a (100) crystal plane.

In an embodiment, a material of the first epitaxial layer includes any one or a combination of a GaN-based material, a GaAs-based material, and an InP-based material.

In an embodiment, the semiconductor structure further includes: a second epitaxial layer located on a side, away from the first substrate, of the first epitaxial layer, where a material of the second epitaxial layer is any one or a combination of a GaN-based material, a GaAs-based material and an InP-based material.

In an embodiment, the second epitaxial includes: an N-type semiconductor layer, an active layer, and a P-type semiconductor layer stacked in sequence.

In an embodiment, the second epitaxial further includes: a buffer layer, located between the N-type semiconductor layer and the mask layer.

In an embodiment, the second epitaxial includes: a channel layer and a barrier layer stacked in sequence.

In an embodiment, the second epitaxial further includes: a buffer layer, located between the channel layer and the mask layer.

In an embodiment, a material of the first substrate includes at least one of silicon, germanium, sapphire and silicon carbide.

According to another aspect of the present disclosure, a manufacturing method for a semiconductor structure is provided by an embodiment of the present disclosure, including: forming a mask layer on a first substrate; etching the mask layer to form a window exposing the first substrate, where the window includes an open end, and an area of an orthographic projection of the open end on a plane where the first substrate is located is less than an area of an orthographic projection of the window on the plane where the first substrate is located; manufacturing a second substrate in the window; and epitaxially growing a first epitaxial layer on the second substrate.

In an embodiment, the manufacturing a second substrate in the window includes: depositing amorphous material in the window, and performing an annealing process, where the amorphous material is converted into a single crystal material, and a material of the second substrate is the single crystal material.

In an embodiment, a material of the second substrate is monocrystalline silicon or monocrystalline germanium, and the manufacturing a second substrate in the window includes: selectively epitaxially growing the second substrate in the window.

In an embodiment, the manufacturing a second substrate in the window includes that a material of the second substrate is monocrystalline silicon or monocrystalline germanium; and before the epitaxially growing a first epitaxial layer on the second substrate, the manufacturing method further includes: processing the second substrate in the window using an alkaline solution, so that a crystal plane, close to the first epitaxial layer, of the second substrate is a (111) crystal plane.

In an embodiment, after the epitaxially growing a first epitaxial layer on the second substrate, the manufacturing method further includes: continually epitaxially growing a second epitaxial layer on a side, away from the first substrate, of the first epitaxial layer, where a material of the second epitaxial layer is any one or a combination of a GaN-based material, a GaAs-based material and an InP-based material.

In an embodiment, a material of the first epitaxial layer includes any one or a combination of a GaN-based material, a GaAs-based material, and an InP-based material.

### BRIEF DESCRIPTION OF THE DRAWINGS

FIG. 1 is a perspective diagram of a three-dimension view of a semiconductor structure according to an embodiment of the present disclosure.

FIG. 2 is a schematic structural diagram of a cross-section of the structure shown in FIG. 1 along a section line AA′.

FIG. 3 is a schematic structural diagram of a semiconductor intermediate structure according to an embodiment of the present disclosure.

FIG. 4 is a schematic structural diagram of a semiconductor intermediate structure according to another embodiment of the present disclosure.

FIG. 5 is a schematic structural diagram of a semiconductor intermediate structure according to still another embodiment of the present disclosure.

FIG. 6 is a schematic structural diagram of a semiconductor intermediate structure according to yet still another embodiment of the present disclosure.

FIG. 7 is a schematic structural diagram of a semiconductor intermediate structure according to yet still another embodiment of the present disclosure.

FIG. 8 is a schematic structural diagram of a semiconductor structure according to an embodiment of the present disclosure.

FIG. 9 is a schematic structural diagram of a semiconductor structure according to another embodiment of the present disclosure.

FIG. 10 is a schematic structural diagram of a light-emitting device according to an embodiment of the present disclosure.

FIG. 11 is a schematic structural diagram of a power device according to an embodiment of the present disclosure.

FIG. 12 is a schematic structural diagram of a semiconductor structure according to an embodiment of the present disclosure.

FIG. 13 is a flowchart of a manufacturing method for a semiconductor structure according to an embodiment of the present disclosure.

FIG. 14 is a flowchart of a manufacturing method for a semiconductor structure according to another embodiment of the present disclosure.

FIG. 15 is a flowchart of a manufacturing method for a semiconductor structure according to still another embodiment of the present disclosure.

### DETAILED DESCRIPTION OF THE EMBODIMENTS

Technical solutions in embodiments of the present disclosure will be clearly and completely described with reference to accompanying drawings corresponding to the embodiments of the present disclosure in the following description. Apparently, the described embodiments are only some, not all, embodiments of the present disclosure.

In order to solve a technical problem that there are many dislocations in a semiconductor film layer in traditional art, the present disclosure provides a semiconductor structure and a manufacturing method therefor.

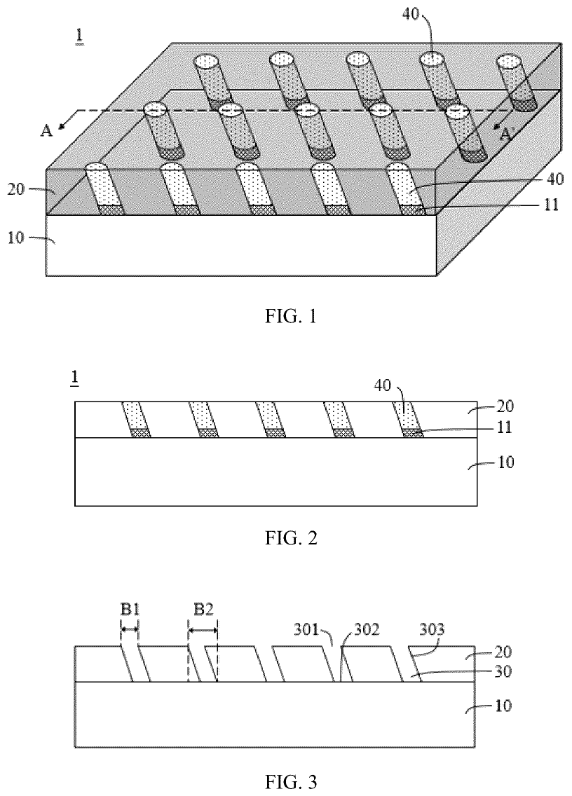

FIG. 1 is a perspective diagram of a three-dimension view of a semiconductor structure according to an embodiment of the present disclosure, FIG. 2 is a schematic structural diagram of a cross-section of the structure shown in FIG. 1 along a section line AA′, and FIG. 3 is a schematic structural diagram of a semiconductor intermediate structure according to an embodiment of the present disclosure. As shown in FIG. 1 to FIG. 3, a semiconductor structure 1 includes a first substrate 10; a mask layer 20, located on the first substrate 10, where the mask layer 20 is provided with a window 30 exposing the first substrate 10, the window 30 includes an open end 301, and an area of an orthographic projection of an open end 301 on a plane where the first substrate 10 is located is less than an area of an orthographic projection of the window 30 on the plane where the first substrate 10 is located; and a second substrate 11 and a first epitaxial layer 40, where the second substrate 11 and the first epitaxial layer 40 are located in the window 30, and the first epitaxial layer 40 is located on a side, away from the first substrate 10, of the second substrate 11.

It should be noted that FIG. 3 illustrates an orthographic projection range of the open end 301 and the window 30 of the section line AA′ on the plane where the first substrate 10 is located, respectively, and an orthographic projection range B1 of the open end 301 is less than an orthographic projection range B2 of the window 30; in other words, the window 30 has a sidewall 303 not perpendicular to the plane where the first substrate 10 is located.

Optionally, a material of the first epitaxial layer 40 includes any one or a combination of III-V compounds, such as a GaN-based material, a GaAs-based material, and an InP-based material. Specifically, taking the GaAs-based material as an example, a line dislocation of the GaAs-based material is substantially consistent with an epitaxial growth direction, and when the GaAs-based material is epitaxially grown in the window 30, a dislocation of the first epitaxial layer 40 terminates at the sidewall 303, and the dislocation may not continue to extend along with a growth of the GaAs-based material, so that a dislocation density of the semiconductor structure may be reduced, and a device characteristic is prevented from being reduced.

Optionally, in the semiconductor structure, there is only one window 30; optionally, as shown in FIG. 3, there is a plurality of windows 30 in the semiconductor structure 1. It should be noted that a shape of a cross-section of the window 30 is not limited and the cross-section is parallel to the plane where the first substrate 10 is located, or a shape of the open end 301 is not limited, or a shape of a bottom end 302 is not limited.

In an embodiment, a material of the second substrate 11 is any one of monocrystalline silicon, monocrystalline germanium, monocrystalline silicon germanium, and monocrystalline silicon carbide. Specifically, monocrystalline silicon, monocrystalline germanium, monocrystalline silicon germanium, and monocrystalline silicon carbide are used as a growth substrate of an III-V compound semiconductor film layer, for example, monocrystalline germanium is used as a growth substrate of a GaAs-based material. As lattice constants and thermal expansion coefficients of GaAs and germanium are similar, a probability of a dislocation during an epitaxial growth of the GaAs-based material may be reduced; similarly, monocrystalline silicon is used as a growth substrate of a GaN-based material. Optionally, a crystal plane, close to the first epitaxial layer 40, of the second substrate 11 is a (111) crystal plane, a (110) crystal plane, or a (100) crystal plane. Specifically, when the material of the second substrate 11 is monocrystalline silicon or monocrystalline germanium, the (111) crystal plane, the (110) crystal plane, or the (100) crystal plane may be more beneficial to an epitaxial growth of the III-V compound. Optionally, crystal quality of the III-V compound epitaxially manufactured on the (111) crystal plane is better. Optionally, a material of the mask layer 20 is silicon oxide or silicon nitride.

In an embodiment, a material of the first substrate 10 is at least one of silicon, germanium, sapphire or silicon carbide. Specifically, the second substrate 11 is used as a growth substrate, and therefore, the present disclosure does not limit the material of the first substrate 10. Optionally, when materials of the first substrate 10 and the second substrate 11 are the same, the second substrate 11 may be manufactured by selective epitaxy; and when materials of the first substrate 10 and the second substrate 11 are different, the second substrate 11 may be manufactured by depositing in the window 30 of the first substrate 10.

Optionally, the first epitaxial layer 40 is a semiconductor film layer including a plurality of materials. Taking GaAs-based material as an example, the first epitaxial layer 40 includes an aluminum-nitrogen nucleation layer and a GaAs-based semiconductor film layer that are sequentially stacked on the second substrate 11.

In an embodiment, as shown in FIG. 3, the window 30 further includes a bottom end 302 located on a surface of the first substrate 10, the orthographic projection of the open end 301 on the plane where the first substrate 10 is located is at least partially staggered from the bottom end 302, and a center of gravity of the open end 301 does not coincide with a center of gravity of the bottom end 302. Specifically, an included angle between the sidewall 303 of the window 30 in FIG. 3 and the plane where the first substrate 10 is located is an acute angle, and a dislocation of the III-V compound terminates at the sidewall 303, so that dislocation density of the semiconductor structure may be reduced.

In an embodiment, as shown in FIG. 3, the window 30 is an oblique columnar window. Specifically, along the section line AA′, the window 30 has a parallelogram shape. The window 30 is manufactured by using dry etching, and an etching direction is controlled, so that the sidewall 303 having an acute included angle with the first substrate 10 is formed. The process is simple and easy to operate.

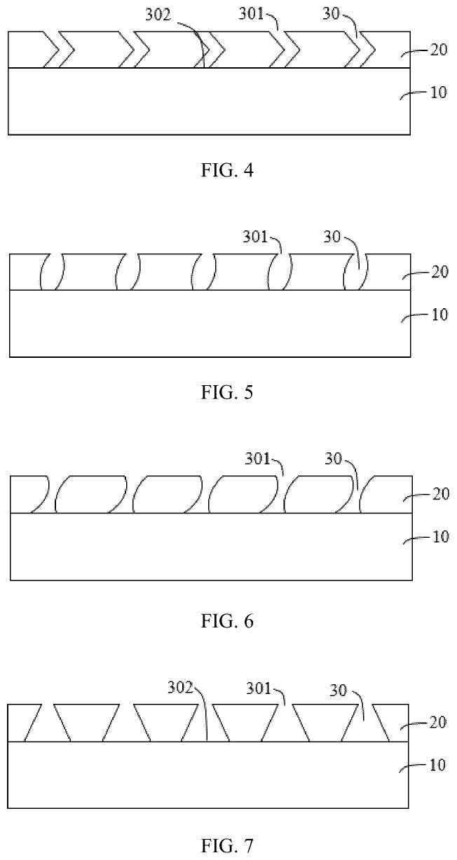

Optionally, FIG. 4 is a schematic structural diagram of a semiconductor intermediate structure according to an embodiment of the present disclosure, as shown in FIG. 4, an orthographic projection of an open end 301 of a window 30 on a plane where a first substrate 10 is located overlaps with a bottom end 302 of the window 30, and an area of an orthographic projection of the open end 301 on the plane where the first substrate 10 is located is less than an area of an orthographic projection of the window 30 on the plane where the first substrate 10 is located. Optionally, a mask layer 20 is manufactured in two steps. A first step is to first manufacture a lower half portion of the mask layer 20, and the lower half portion of the window 30 exposing the first substrate 10 is manufactured by using dry etching. And a second step is to manufacture an upper half portion of the mask layer 20, the upper half portion of the window 30 is manufactured by using dry etching, and the upper half portion of the window 30 is connected to the lower half portion of the window 30, where directions of two times of dry etching are inconsistent.

Optionally, FIG. 5 is a schematic structural diagram of a semiconductor intermediate structure according to another embodiment of the present disclosure, and FIG. 6 is a schematic structural diagram of a semiconductor intermediate structure according to still another embodiment of the present disclosure. As shown in FIG. 5, in a direction from a first substrate 10 to an open end 301, a cross-sectional area of a window 30 parallel to a plane where the first substrate 10 is located increases first and then decreases; as shown in FIG. 6, in a direction from a first substrate 10 to an open end 301, a cross-sectional area of a window 30 parallel to a plane where the first substrate 10 is located decreases first and then increases.

In an embodiment, FIG. 7 is a schematic structural diagram of a semiconductor intermediate structure according to yet still another embodiment of the present disclosure. As shown in FIG. 7, a window 30 further includes a bottom end 302 located on a surface of the first substrate 10, and an orthographic projection of an opening end 301 on a plane where the first substrate 10 is located falls within an orthographic projection of the bottom end 302 on the plane where the first substrate 10 is located. Specifically, an area of the bottom end 302 is greater than an area of the open end 301; and the window 30 has a trapezoidal shape along the section line AA′.

In an embodiment, as shown in FIG. 7, in a direction from the bottom end 302 to the open end 301, a cross-sectional area of the window 30 gradually decreases. Specifically, when III-V compound is epitaxially grown in the window 30, since a left sidewall and a right sidewall of the window 30 form a bundling state, a dislocation of the first epitaxial layer 40 terminates at two sidewalls, and the dislocation may not continue to extend along with the growth of the III-V compound, so that dislocation density of the semiconductor structure may be reduced.

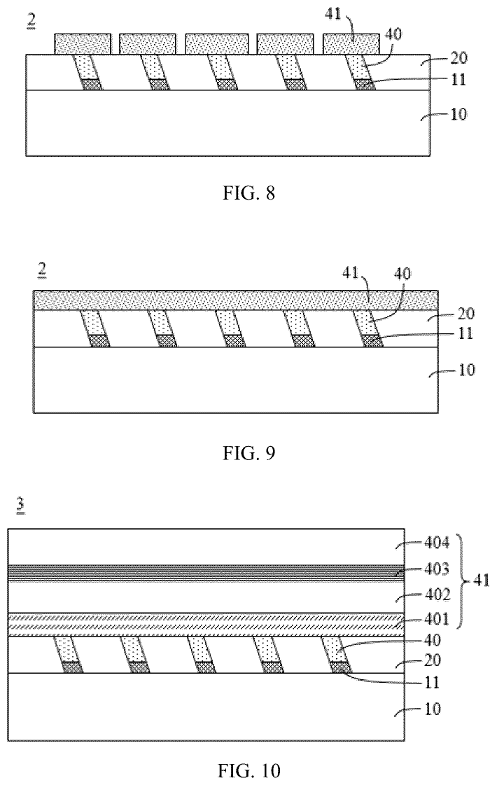

In an embodiment, FIG. 8 is a schematic structural diagram of a semiconductor structure according to an embodiment of the present disclosure. As shown in FIG. 8, a semiconductor structure 2 further includes a second epitaxial layer 41 located on a side, away from a first substrate 10, of a first epitaxial layer 40, and a material of the second epitaxial layer 41 is any one or a combination of a GaN-based material, a GaAs-based material and an InP-based material. Specifically, the second epitaxial layer 41 epitaxially grows, from the first epitaxial layer 40 located at the open end 301, on the mask layer 20; and optionally, the second epitaxial layer 41 extends laterally, so that a bottom area of the second epitaxial layer 41 is greater than the orthographic projection area of the open end 301 on the plane where the first substrate 10 is located.

It should be noted that, taking the GaAs-based material as an example, materials of the first epitaxial layer 40 and the second epitaxial layer 41 may be the same. For example, both the materials of the first epitaxial layer 40 and the second epitaxial layer 41 are GaAs. Optionally, materials of the first epitaxial layer 40 and the second epitaxial layer 41 may be different. For example, the material of the first epitaxial layer 40 includes GaAs, and the material of the second epitaxial layer 41 includes any one of InGaAs or AlGaAs. And optionally, the material of the first epitaxial layer 40 includes GaAs, and the material of the second epitaxial layer 41 includes a semiconductor film layer of a plurality of GaAs-based materials.

Optionally, FIG. 9 is a schematic structural diagram of a semiconductor structure according to another embodiment of the present disclosure, as shown in FIG. 9, the second epitaxial layer 41 extends laterally and heals to form a flat surface.

In an embodiment, FIG. 10 is a schematic structural diagram of a light-emitting device according to an embodiment of the present disclosure. As shown in FIG. 10, a light-emitting device 3 includes a second epitaxial layer 41 which has been formed to be a flat surface, and the second epitaxial layer 41 includes: an N-type semiconductor layer 402, an active layer 403 and a P-type semiconductor layer 404 stacked in sequence. Specifically, taking the material of the second epitaxial layer 41 being a GaAs-based material as an example, a material of the N-type semiconductor layer 402 is an N-type GaAs, the active layer 403 is a multi-quantum well layer composed of GaAs and GaAs-based ternary or quaternary compounds, and a material of the P-type semiconductor layer 404 is a P-type GaAs.

Optionally, as shown in FIG. 10, the second epitaxial layer 41 further includes a buffer layer 401 located between the N-type semiconductor layer 402 and the mask layer 20. Optionally, a first epitaxial layer 40 of the light-emitting device 3 is used as a buffer layer, and the second epitaxial layer 41 does not include the buffer layer 401.

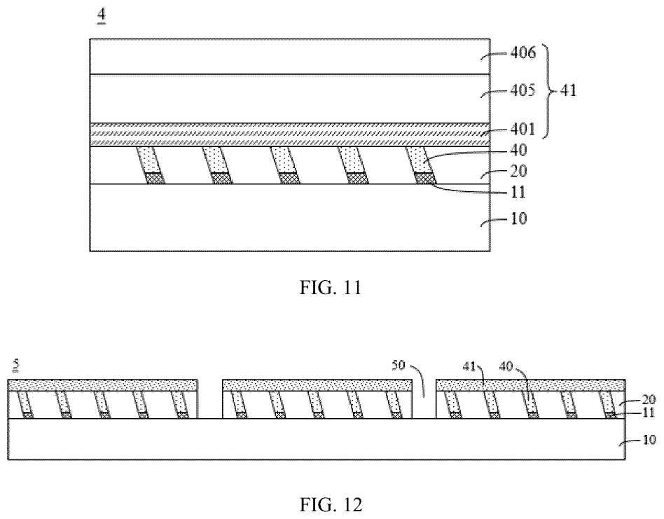

In an embodiment, FIG. 11 is a schematic structural diagram of a power device according to an embodiment of the present disclosure. As shown in FIG. 11, a power device 4 includes a second epitaxial layer 41 forming a flat surface, and the second epitaxial layer 41 includes a channel layer 405 and a barrier layer 406 stacked in sequence. Specifically, taking the second epitaxial layer 41 being made of a GaN-based material as an example, the channel layer 405 is made of GaN, and the barrier layer 406 is made of AlGaN.

Optionally, as shown in FIG. 11, the second epitaxial layer 41 further includes a buffer layer 401 located between the channel layer 405 and the mask layer 20. Optionally, a first epitaxial layer 40 of the power device 4 is used as a buffer layer, and the second epitaxial layer 41 does not include the buffer layer 401.

In an embodiment, FIG. 12 is a schematic structural diagram of a semiconductor structure according to an embodiment of the present disclosure. As shown in FIG. 12, a semiconductor structure 5 includes a first substrate 10, a plurality of mask layers 20 disposed on the first substrate 10, a second substrate 11 and a first epitaxial layer 40 both located in a window of the mask layer 20, and a second epitaxial layer 41 located on the mask layer 20. The second epitaxial layer 41 may be manufactured as an independent device. Optionally, the semiconductor structure 5 further includes a trench 50 located between two sets of the mask layers 20. After the second substrate 11 is manufactured, the trench 50 is formed by etching, and then the first epitaxial layer 40 and the second epitaxial layer 41 are manufactured by epitaxy.

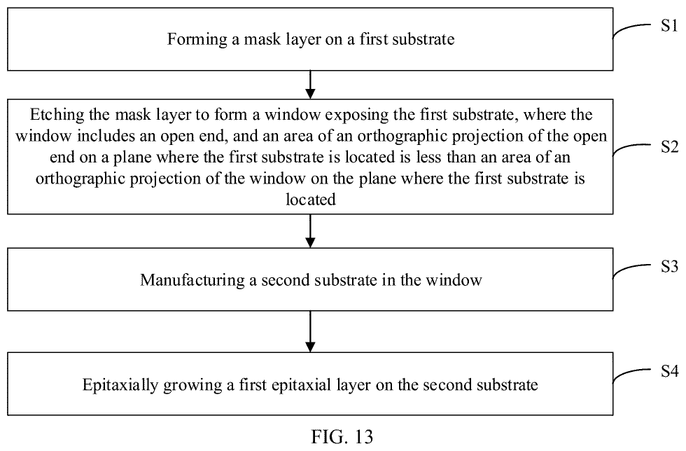

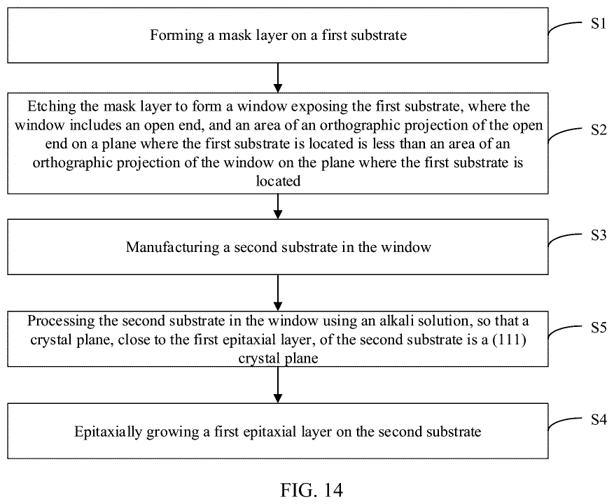

FIG. 13 is a flowchart of a manufacturing method for a semiconductor structure according to an embodiment of the present disclosure. As shown in FIG. 13, an embodiment of the present disclosure further provides a manufacturing method for a semiconductor structure, including following steps.

Step S1: forming a mask layer on a first substrate. Optionally, a material of the first substrate 10 is at least one of silicon, germanium, sapphire or silicon carbide, and a material of the mask layer 20 is silicon oxide or silicon nitride.

Step S2: etching the mask layer to form a window exposing the first substrate, where the window includes an open end, and an area of an orthographic projection of the open end on a plane where the first substrate is located is less than an area of an orthographic projection of the window on the plane where the first substrate is located. As shown in FIG. 3, Optionally, an orthographic projection range B1 of the open end 301 is less than an orthographic projection range B2 of the window 30, and the window 30 has a sidewall 303 not perpendicular to the plane where the first substrate 10 is located. Optionally, a dry etching method or a wet etching method is used to etching the mask layer 20, and a person skilled in the art may use a suitable etching method according to the shape of the required window 30.

Step S3, manufacturing a second substrate in the window.

Optionally, the manufacturing a second substrate 11 in the window 30 includes: depositing amorphous material in the window, and performing an annealing process, where the amorphous material is converted into a single crystal material, and a material of the second substrate is the single crystal material. Specifically, the amorphous material is amorphous silicon or amorphous germanium. After the performing an annealing process, amorphous silicon and amorphous germanium are respectively converted into monocrystalline silicon and monocrystalline germanium, and monocrystalline silicon and monocrystalline germanium may be used as a growth substrate of an III-V compound.

Optionally, a material of the second substrate 11 is monocrystalline silicon or monocrystalline germanium, and the manufacturing a second substrate 11 in the window 30 includes: selectively epitaxially growing the second substrate 11 on the window 30. Specifically, a material of the first substrate 10 is silicon or germanium, and monocrystalline silicon or monocrystalline germanium is selectively epitaxially manufactured in the window 30.

Step S4: epitaxially growing a first epitaxial layer on the second substrate. As shown in FIG. 2. Specifically, a material of the first epitaxial layer 40 includes an III-V compound, such as any one or a combination of a GaN-based material, a GaAs-based material and an InP-based material. A line dislocation of the III-V compound is substantially consistent with an epitaxial growth direction, so that when the III-V compound is epitaxially grown in the window 30, a dislocation of the first epitaxial layer 40 terminates at the sidewall, and the dislocation may not continue to extend along with a growth of the III-V compound. Therefore, dislocation density of the semiconductor structure may be reduced.

FIG. 14 is a flowchart of a manufacturing method for a semiconductor structure according to another embodiment of the present disclosure. As shown in FIG. 14, in an embodiment, a material of the second substrate 11 is monocrystalline silicon or monocrystalline germanium; and before the epitaxially growing a first epitaxial layer 40 on the second substrate 11, the manufacturing method further includes step S5: processing the second substrate in the window using an alkaline solution, so that a crystal plane, close to the first epitaxial layer, of the second substrate is a (111) crystal plane. Specifically, the material of the second substrate 11 is monocrystalline silicon or monocrystalline germanium, and before an alkaline solution treatment is performed, the second substrate 11 is a (100) crystal plane, and after the process of using the alkaline solution is performed, the (100) crystal plane in the window 30 is converted into a (111) crystal plane, and the (111) crystal plane is more beneficial to an epitaxial growth of an III-V compound in the window 30.

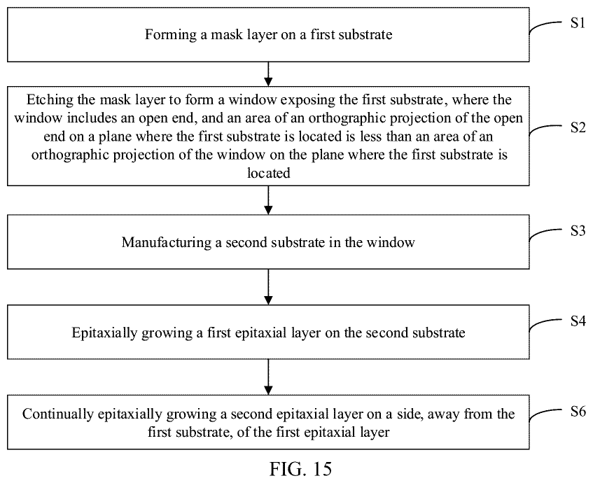

FIG. 15 is a flowchart of a manufacturing method for a semiconductor structure according to still another embodiment of the present disclosure. As shown in FIG. 15, in an embodiment, as shown in FIG. 8 and FIG. 9, after epitaxially growing a first epitaxial layer 40 in the window 30, the manufacturing method further includes step S6: continually epitaxially growing a second epitaxial layer on a side, away from the first substrate, of the first epitaxial layer, where a material of the second epitaxial layer is any one or a combination of a GaN-based material, a GaAs-based material and an InP-based material. Optionally, as shown in FIG. 8, the second epitaxial layers 41 are in one-to-one correspondence with the windows 30, and a subsequent manufacturing of a semiconductor device is independent of each other. As shown in FIG. 9, the second epitaxial layer 41 extends laterally and heals to form a flat surface. As shown in FIG. 10 and FIG. 11, a subsequently manufactured semiconductor device corresponds to a plurality of windows 30.

A semiconductor structure provided by an embodiment of the present disclosure includes: a first substrate; a mask layer, located on the first substrate; where the mask layer is provided with a window exposing the first substrate, the window includes an open end, and an area of an orthographic projection of the open end on a plane where the first substrate is located is less than an area of an orthographic projection of the window on the plane where the first substrate is located, that is, the window has a sidewall that is not perpendicular to the plane where the first substrate is located; and a second substrate located in the window, where when a first epitaxial layer is epitaxially grown on the second substrate, a dislocation of the first epitaxial layer terminates at the sidewall, the dislocation may not continue to extend along with a growth of the first epitaxial layer, so that a dislocation density of the semiconductor structure may be reduced, and device characteristic may be improved.

It should be understood that terms “comprising” and variations thereof used in the present disclosure are open-ended, that is, “including but not limited to”. Term “an embodiment” means “at least one embodiment”. In the specification, the specific features, structures, materials, or characteristics described may be combined in any suitable manner in any one or more embodiments or examples. In addition, in the case of no contradiction, a person skilled in the art may combine and combine different embodiments or examples described in this specification and features of different embodiments or examples.

What is claimed is:

1. A semiconductor structure, comprising:
a first substrate;
a mask layer, located on the first substrate, wherein the mask layer is provided with a window exposing the first substrate, the window comprises an open end, and an area of an orthographic projection of the open end on a plane where the first substrate is located is less than an area of an orthographic projection of the window on the plane where the first substrate is located; and
a second substrate and a first epitaxial layer, wherein the second substrate and the first epitaxial layer are located in the window, and the first epitaxial layer is located on a side, away from the first substrate, of the second substrate.

2. The semiconductor structure according to claim 1, wherein the window further comprises a bottom end located on a surface of the first substrate, and the orthographic projection of the open end on the plane where the first substrate is located is at least partially staggered from the bottom end.

3. The semiconductor structure according to claim 2, wherein the window is an oblique columnar window.

4. The semiconductor structure according to claim 1, wherein the window further comprises a bottom end located on a surface of the first substrate, and the orthographic projection of the open end on the plane where the first substrate is located within an orthographic projection of the bottom end on the plane where the first substrate is located.

5. The semiconductor structure according to claim 4, wherein a cross-sectional area of the window gradually decreases in a direction from the bottom end to the open end.

6. The semiconductor structure according to claim 1, wherein a material of the second substrate is any one of monocrystalline silicon, monocrystalline germanium, monocrystalline silicon germanium, and monocrystalline silicon carbide.

7. The semiconductor structure according to claim 6, wherein a crystal plane, close to the first epitaxial layer, of the second substrate is any one of a (111) crystal plane, a (110) crystal plane and a (100) crystal plane.

8. The semiconductor structure according to claim 1, wherein a material of the first epitaxial layer comprises any one or a combination of a GaN-based material, a GaAs-based material, and an InP-based material.

9. The semiconductor structure according to claim 1, further comprising:
a second epitaxial layer located on a side, away from the first substrate, of the first epitaxial layer, wherein a material of the second epitaxial layer is any one or a combination of a GaN-based material, a GaAs-based material and an InP-based material.

10. The semiconductor structure according to claim 9, wherein the second epitaxial comprises: an N-type semiconductor layer, an active layer, and a P-type semiconductor layer stacked in sequence.

11. The semiconductor structure according to claim 10, wherein the second epitaxial further comprises: a buffer layer, located between the N-type semiconductor layer and the mask layer.

12. The semiconductor structure according to claim 9, wherein the second epitaxial comprises: a channel layer and a barrier layer stacked in sequence.

13. The semiconductor structure according to claim 12, wherein the second epitaxial further comprises: a buffer layer, located between the channel layer and the mask layer.

14. The semiconductor structure according to claim 1, wherein a material of the first substrate comprises at least one of silicon, germanium, sapphire and silicon carbide.

15. A manufacturing method for a semiconductor structure, comprising:
forming a mask layer on a first substrate;
etching the mask layer to form a window exposing the first substrate, wherein the window comprises an open end, and an area of an orthographic projection of the open end on a plane where the first substrate is located is less than an area of an orthographic projection of the window on the plane where the first substrate is located;
manufacturing a second substrate in the window; and
epitaxially growing a first epitaxial layer on the second substrate.

16. The manufacturing method according to claim 15, wherein the manufacturing a second substrate in the window comprises:
depositing amorphous material in the window, and performing an annealing process, wherein the amorphous material is converted into a single crystal material, and a material of the second substrate is the single crystal material.

17. The manufacturing method according to claim 15, wherein a material of the second substrate is monocrystalline silicon or monocrystalline germanium, and
the manufacturing a second substrate in the window comprises:
selectively epitaxially growing the second substrate in the window.

18. The manufacturing method according to claim 15, wherein a material of the second substrate is monocrystalline silicon or monocrystalline germanium; and
before the epitaxially growing a first epitaxial layer on the second substrate, the manufacturing method further comprises:
processing the second substrate in the window using an alkaline solution, so that a crystal plane, close to the first epitaxial layer, of the second substrate is a (111) crystal plane.

19. The manufacturing method according to claim 15, wherein after the epitaxially growing a first epitaxial layer on the second substrate, the manufacturing method further comprises:
continually epitaxially growing a second epitaxial layer on a side, away from the first substrate, of the first epitaxial layer, wherein a material of the second epitaxial layer is any one or a combination of a GaN-based material, a GaAs-based material and an InP-based material.

20. The manufacturing method according to claim 15, wherein a material of the first epitaxial layer comprises any one or a combination of a GaN-based material, a GaAs-based material, and an InP-based material.
